(19) United States
(12) Patent Application Publication
(10) Pub. No.: US 2003/0232150 A1
(43) Pub. Date: Dec. 18, 2003

(54) CVD coating device

(76) Inventors: Gregor Arnold, Bodenheim (DE); Stephen Behle, Hahnheim (DE); Andreas Luttringhaus-Henkel, Darmstadt (DE); Matthias Bicker, Mainz (DE)

Correspondence Address: M. Robert Kestenbaum, 11011 Bermuda Dunes NE, Albuquerque, NM, 87111, US

(21) Appl. No.: 10/445,566

(22) Filed: May 26, 2003

(30) Foreign Application Priority Data
May 24, 2002 (DE) 102 23 288.1
Jun. 4, 2002 (DE) 102 24 934.2-45
Jun. 7, 2002 (DE) 102 25 609.8
Jun. 20, 2002 (DE) 102 27 637.4

(51) Int. Cl. C23C 16/00

(52) U.S. Cl. 427/569; 118/718; 118/719; 118/723 MW; 427/575; 427/255.11

(57) ABSTRACT

To enable CVD coating with long coating times in an economical manner, the invention provides a CVD coating device, which comprises a conveyor, at least one coating station for coating workpieces, at least one evacuator and a device that generates a plasma in at least one subregion of the coating station, in which device at least two workpieces can be received in the at least one coating station.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

The invention relates to a device for the CVD coating of workpieces, in particular to a device for the simultaneous coating of a plurality of workpieces.

### TECHNICAL FIELD

To improve the barrier actions in particular of plastic containers, such as for example plastic bottles, the latter may be provided with barrier layers. Coatings of this type can be deposited on the container walls inter alia by means of various CVD processes (CVD: chemical vapor deposition).

The plasma impulse CVD (PICVD) process (pulsed microwave plasma) is a particularly suitable deposition process for plastic containers. Compared to plasma-enhanced chemical vapor deposition (PECVD), in which the plasma is maintained continuously, the PICVD process-is advantageous inter alia because the process makes it possible to reduce the extent to which the temperature-sensitive plastics are heated. Moreover, gas exchange becomes possible during the periods of time outside the pulses, in which no plasma is excited.

For this purpose, in coating installations on a laboratory scale, the plastic containers are inserted into a coating station, this station being fully equipped with all the technical means which are required for the coating. These include, inter alia, vacuum pumps, gas supply, sensors and the introduction of microwaves. After a vacuum-tight bell jar has been closed, the hollow body can be evacuated on the inside and outside and the coating of the inner and/or outer side of the container can be carried out.

For coatings on an industrial scale, this requires a machine with a correspondingly high capacity. By way of example, continuously running rotary conveyors with radially arranged, identical coating stations are suitable for this purpose.

It is a problem in this context if the layers which are to be deposited require long coating times. By way of example, certain coatings may require the coating times alone to be longer than 20 seconds. Long residence times in the coating sections are also required if the coating is to take place in a plurality of steps. This is conceivable, by way of example, if the surface of plastic bodies is to be activated prior to the coating or if a plurality of layers need to be applied in succession. In these cases, a continuously running rotary conveyor device can no longer be operated economically, since it either has to run correspondingly slowly or its size has to be matched to the process times, which requires very large and correspondingly expensive machines.

### SUMMARY OF THE INVENTION

Therefore, the invention is based on the object of making the CVD coating more economical even for long process times.

Accordingly, a CVD coating device according to the invention comprises a conveyor, at least one coating station for coating workpieces, at least one evacuation device and a plasma generator for generating a plasma in at least one subregion of the coating station, in which device at least two workpieces can be received in the at least one coating station.

The fact that the coating station can receive a plurality of workpieces simultaneously means that with a throughput which remains the same the process times are increased by a factor which corresponds to the number of workpieces which can be received in the coating station. This ensures that the dimensions of the device can be kept small yet nevertheless long coating times can be implemented combined, at the same time, with a high throughput.

Furthermore, for many embodiments it is expedient if the at least one coating station is conveyed with the conveyor.

The plasma generator for generating a plasma in at least one subregion of the coating station preferably comprises a means for generating a pulsed plasma. A plasma generator of this type allows PICVD coating of the workpieces, with the advantages listed above.

A plurality of workpieces can be received in a simple manner by their being arranged on at least one holder which can be received in the at least one coating station. In this case, the workpieces may be either in a single plane or stacked in a plurality of planes in a three-dimensional arrangement.

Furthermore, the device may advantageously be configured in such a way that the conveyor successively conveys the coating station from at least one feed position to at least one pumping position, at least one coating position and at least one unloading position. In particular, the device may have at least four coating stations, which are arranged on the conveyor in such a way that in each case one of the coating stations is in the feed position, the evacuation position and the unloading position when one of the coating stations is in the coating position. This enables each of the coating stations to be taking part in one step of the process sequence, so that the process sequence is optimized in terms of time.

The process sequence can also be optimized by the conveyor slowing the conveying speed during coating. In this context, it is advantageous in particular if the conveyor stops during the coating. The resulting deviation from a continuous production process results in better time utilization of the phases of the production process, which generally are of different length.

According to an embodiment of the invention, the conveyor comprises a rotary device. These can be produced in particularly compact form and with a relatively simple mechanism. However, it is also possible to use a rectilinear system which, by way of example, offers the advantage of free access to the coating stations from two opposite sides.

A plasma can be generated in at least one subregion of the coating station in a simple manner by means of a device that generates electromagnetic waves. In this context, it is advantageous to generate microwaves, which can be easily conveyed through hollow waveguides and can transmit high energy densities.

Furthermore, it is expedient if the device according to the invention includes a means for connecting the device that generates electromagnetic waves to the at least one coating station. The result of this is that it is not necessary for the device that generates electromagnetic waves to be carried along with the coating stations. Rather, a device of this type can be used to connect the device that generates electromagnetic waves to the at least one coating station only when a defined coating region is reached.

For a simple structure of the device, it is advantageous if the device that generates electromagnetic waves is arranged in a stationary position. This avoids the device having to be carried along with the at least one coating station. In particular, this ensures that it is not necessary for each coating station to have a dedicated plasma generator which has to be carried along on the conveyor and would therefore hugely increase the outlay on apparatus for a CVD coating device.

To enable the final pressure required for plasma coating to be reached more quickly, at least two and preferably more pump devices or pump stages are advantageous. The pump stages can be optimized for different pressure ranges. Sequentially switching the pump stages on and off then enables the final pressure to be reached quickly with a pump capacity which is greatly reduced compared to a single pump stage.

Moreover, the device according to the invention may also include a device that sequentially connecting the at least one coating station to the at least two pump stages. This may, for example, produce the connection to the coating station at defined positions of the conveyor, for example at dedicated rotary positions in the case of a rotary conveyor.

To reliably fix the workpieces during the evacuation and coating, the device according to the invention may also include securing means for the at least two workpieces. The securing means may in particular also comprise receiving means for workpieces which are in the form of hollow bodies, in particular for bottles.

Moreover, a means for admitting process gases is advantageous for all embodiments of the invention. To coat hollow bodies, such as plastic bottles or glass bottles, this means may also be designed in such a way that the process gases are admitted to the hollow body. If the hollow body is fixed in a sealing receiver, it is in this way possible to generate different gas compositions in the inner region and outer region of the hollow body. In this way, it is possible to produce different layers on the inner and outer walls of the hollow bodies or, for example, to produce only internal or external coatings if the gas compositions are selected in such a manner that a plasma is generated by the action of electromagnetic radiation only in the inner or outer region.

It is also part of the scope of the invention to provide a process for CVD coating workpieces that allows coating to be achieved at a reasonable cost, even with long process times. The process for CVD coating workpieces, which can be carried out in particular using a device according to the invention, comprises the steps of:

introducing at least two workpieces into a coating station,

evacuating,

conveying the at least two workpieces with a conveyor,

generating a plasma in at least one subregion of the coating station,

venting, and

removing the workpieces.

The generation of a plasma in at least one subregion leads to chemical reactions between the constituents of the process gas that forms the plasma. The starting materials of the reactions in the plasma are then deposited as a coating on those surfaces of the workpieces that adjoin the plasma.

By treating a plurality of workpieces in a joint coating station in which the plasma is generated, it is possible to lengthen the process time according to the number of workpieces treated or coated together without reducing the throughput. To exploit the advantage of coating in a common coating station, the step of generating a plasma in at least one subregion also comprises the step of joint CVD coating of at least two workpieces.

Furthermore, for different variants of the process according to the invention, it is advantageous if the at least one coating station is conveyed with the conveyor. In this way, by way of example, the workpieces are conveyed onward together with the coating station in which the workpieces are received, and as a result various treatment steps can be performed during the movement of the conveyor.

A configuration of the process in which the step of generating a plasma in at least one subregion of the coating station comprises the step of generating a pulsed plasma. A pulsed plasma inter alia enables high powers to be converted in the plasma during a pulse, while at the same time the mean power over the course of time is kept at a low level.

Arranging the workpieces on holders that are introduced into the coating station is advantageous for the process according to the invention, since this step can be carried out outside the coating device, with the result that space is created for corresponding devices, such as, for example, robot gripper arms.

Favorable utilization of space can be achieved if the workpieces are arranged on at least two levels in the coating station. This can be achieved, for example, by means of a suitable arrangement on a holder.

Moreover, the step of conveying the coating station with a conveyor may advantageously comprise the steps of conveying from a feed position to an evacuation position, a coating position and an unloading position.

To further optimize the sequence of the process in terms of time, the step of conveying the coating station with a conveyor may furthermore comprise the step of slowing the conveying speed during the coating, in particular the step of stopping during the coating.

Furthermore, the step of generating a plasma in at least one subregion of the coating station comprises the step of generating electromagnetic waves, in particular of generating microwaves. Furthermore, the step of generating a-plasma may comprise the step of admitting a process gas.

According to a refinement of the invention, the process also comprises the step of connecting that generates electromagnetic waves to the at least one coating station. In this way, the electromagnetic waves can be generated using a stationary means while the conveyor with the coating station can move past it and in the process be connected to the means for generating electromagnetic waves.

To quickly reach the final pressure required during evacuation, the evacuation step may additionally comprise the step of sequential evacuation using at least two pump stages.

To effect internal coating of workpieces that are in the form of hollow bodies, such as in particular bottles, it is expedient for the cavity which is surrounded by the workpieces which are in the form of hollow bodies also to be evacuated. Therefore, according to this refinement, for example when bottles are being coated, the interior of the bottle is evacuated. Furthermore, to coat workpieces of this type, it is expedient if the step of admitting a process gas comprises the step of admitting a process gas to the cavity in workpieces that are in the form of hollow bodies.

### BRIEF DESCRIPTION OF THE DRAWINGS

The invention is described in more detail below, by way of example, on the basis of embodiments and with reference to the appended drawings. In the drawings, identical reference symbols denote identical or similar parts, and:

FIG. 1 shows a diagrammatic plan view of a first embodiment of the invention with a rotary conveyor,

FIG. 2 shows a diagrammatic plan view of a second embodiment of the invention with a rotary conveyor,

FIG. 3 shows a diagrammatic plan view of a third embodiment of the invention with a rotary conveyor, and

FIG. 4 shows a diagrammatic plan view of a device according to the invention designed as a rectilinear conveyor.

### DETAILED DESCRIPTION OF THE INVENTION

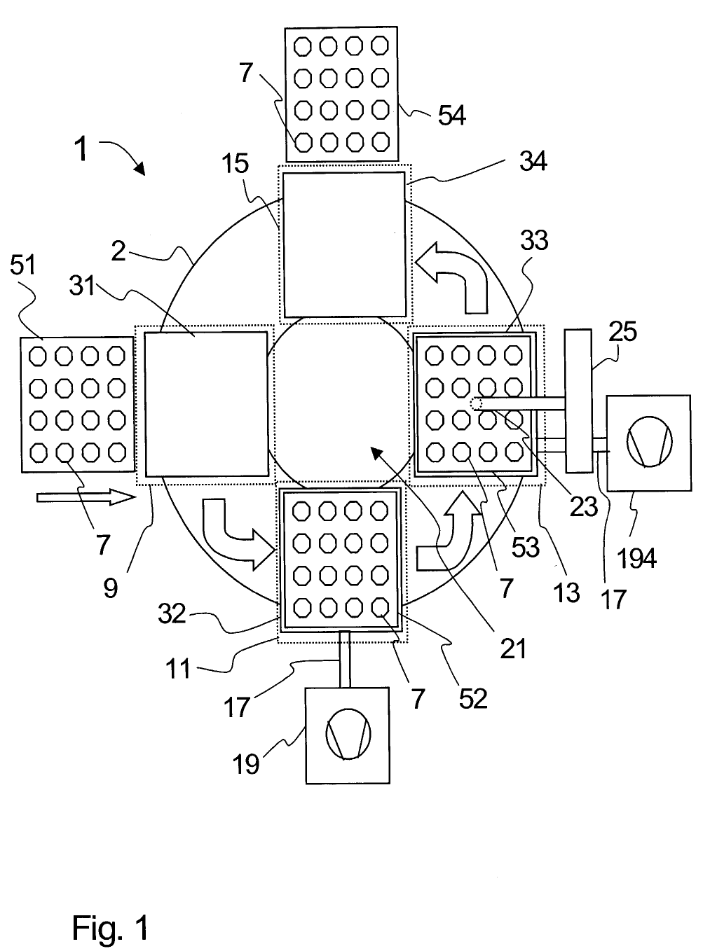

FIG. 1 illustrates a diagrammatic plan view of a first embodiment of the CVD coating device according to the invention, which is denoted overall by 1. In this embodiment, the device 1 comprises a conveyor 2 in the form of a rotary conveyor. Four coating stations 31, 32, 33, 34 are secured to the rotary conveyor 2.

The workpieces that are to be coated are arranged on holders in the form of pallets 51, 52, 53, 54 that are fed to the coating stations 31-34.

The workpieces are secured on the pallets in suitable securing means or receiving means 7. The operations of arranging the workpieces on the pallets and of removing them from the pallets may in this case be carried out, for example, by robot gripper arms. In the embodiment of the device 1 shown in FIG. 1, there are in each case 16 receiving means 7 on one pallet. Accordingly, in each case 16 workpieces can be coated simultaneously in one coating station.

The workpieces secured to one of the pallets 51-54 are supplied to a coating station 31-34 when the coating station on the conveyor 2 is in a feed position 9. The feed position corresponds to a defined rotary angle or rotary angle range of the rotary conveyor.

In one of the coating stations (in FIG. 1) the coating station 31 is in the feed position. In this case one of the other coating stations 32, 33, 34 is in an evacuation position 11, a coating position 13, and an unloading position 15, respectively.

When the pallet has been fed to the coating station 31, the latter can be closed and the coating stations are conveyed onward on the conveyor 2 until the coating station 31 reaches the pumping position 11. In the state of the device shown in FIG. 1, the coating station 32 with the pallet 52 that has been received therein is in the pumping position. In this position, the coating station 32 is connected to an evacuator 19 by means of a suitable means. In this embodiment, the connecting means comprises vacuum lines 17. The evacuator may, for example, comprise combinations of different types of pumps that are sequentially connected by the connecting means in order to provide an optimum pumping capacity for the pressure instantaneously prevailing in the coating station 32. The evacuator 19 may also, contrary to what is shown in FIG. 1, be arranged in the inner region 21 of the rotary conveyor, in order to achieve the most compact structure of the device 1 possible.

After the coating station has been evacuated, the conveyor is moved onward until the coating station is in the coating position 13. In the coating position 13, a means 25 for generating microwaves is connected to the coating station. By way of example, this can be effected by means of suitable hollow waveguides 23, even though only a single hollow waveguide is shown in FIG. 1. For all the embodiments described here, it is also expedient if the coating stations are connected by means of a plurality of hollow waveguides 23, for example one hollow waveguide per workpiece, in order to produce a uniform distribution of the radiation in the coating station.

Moreover, in the coating station 13, the process gas which is suitable for the coating is admitted to the coating station and is adjusted to the required process pressure by means of a pump device 194 comprising suitable pumps. Moreover, the pump device 194 which is connected to the coating station located in each case in the coating position 13 by means of a feedline 17 can pump out the process gases which are supplied during the coating via a means which is not shown, with the result that gas exchange becomes possible during the coating operation. Then, a plasma is generated in the interior of the coating station by means of the microwaves which are radiated into the coating station by the means 25, with the result that the chemical reactions which are set in motion in the plasma cause a CVD layer to be formed on those surfaces of the workpieces which are located in the region of the plasma.

In particular, in the case of workpieces that are in the form of hollow bodies, such as plastic bottles, the gas may also be admitted to the interior of the hollow body. For this purpose, receiving means 7 of the pallets are designed in such a way that, together with the workpiece secured thereon, they create a closed cavity that is partly delimited by the inner walls of the workpieces that are in the form of hollow bodies. The process gas is then admitted to this cavity. When the microwaves are radiated in, plasma is formed and layers are deposited in the interior of the workpieces or in the cavities formed by receiving means 7 and workpiece. In this way, internal coating of workpieces which are in the form of hollow bodies can be carried out. If the process gas is only introduced into the cavities, a plasma is not formed outside the cavities if the pressure produced by the evacuation is too low. Alternatively, the evacuator 19 can also be used to evacuate only the cavities which are formed, with the result that the remaining parts of the coating station are under standard pressure. In this case, on account of the high gas density and the associated short free path length of the gas molecules, a plasma is not formed in these parts of the coating station.

Furthermore, in the case of workpieces which are in the form of hollow bodies, it is also possible for various process gases to be introduced into the cavities and the remaining regions in the coating station. In this way, the inner and outer walls of the workpieces can be provided with various types of layers. By way of example, plastic bottles may expediently be provided with an internal coating with a diffusion barrier and an external coating with a UV-resistant layer.

After the coating operation has ended, the coating station is then conveyed onward with the conveyor to an unloading position 15, where the pallet with the coated workpieces is removed by means of a suitable device.

The conveyor can move continuously throughout the entire process sequence. However, it is advantageous if the conveyor stops during the coating operation, so that with a stationary means 25 for generating microwaves the hollow waveguides 23 do not need to be moved. The operations of connecting to the evacuator 19 and pumping out can also be effected without difficulty if the conveyor is stationary.

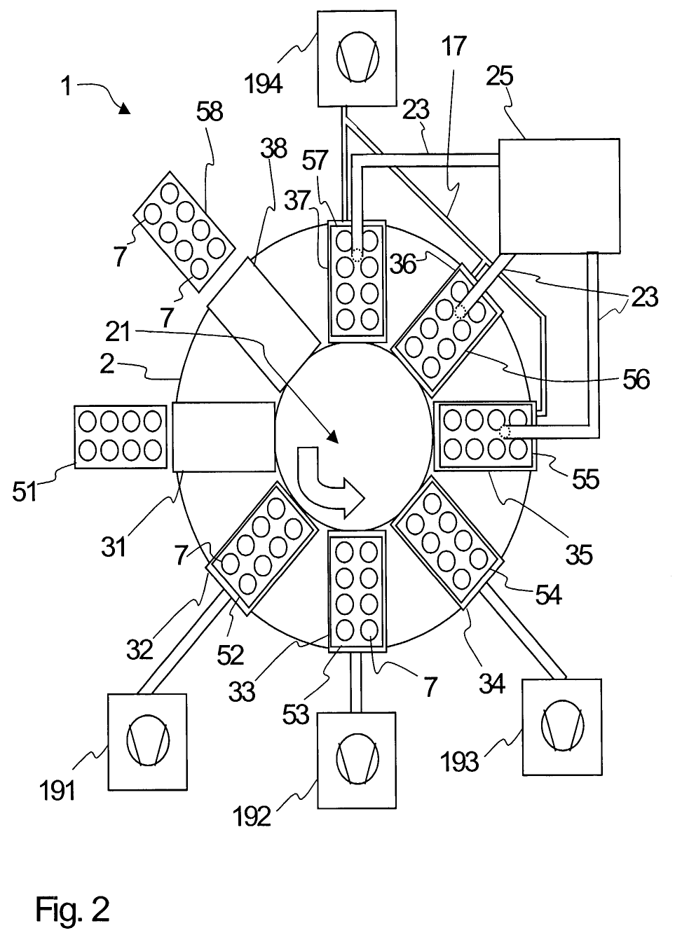

The following text refers to FIG. 2, which diagrammatically depicts a further embodiment of the device 1 according to the invention.

This embodiment of the CVD coating device 1 comprises eight coating stations 31-38. The holders in the form of pallets 51-58 are suitable for receiving in each case eight workpieces. Contrary to the embodiment which has been illustrated with reference to FIG. 1, the coating stations 31-38 are successively fed, together with the conveyor, to a plurality of evacuation positions and coating positions. The block-shaped arrow indicates the direction of rotation of the rotary conveyor.

In the state shown in FIG. 2, the coating station 32 is in a first evacuation position, the coating station 33 is in a second evacuation position and the coating station 34 is in a third evacuation position.

In this embodiment of the invention, the evacuator for evacuating the coating stations comprises pump devices 191, 192 and 193 for each of the evacuation positions, and a coating station located in one of these positions is connected to each of these pump devices 191, 192, 193.

In this way, the coating stations are evacuated in steps to defined vacuum pressures. The pump devices may preferably be optimized for different pressure ranges, in order to achieve effective evacuation of the coating stations even with a relatively low pump capacity.

Furthermore, the embodiment shown in FIG. 2 differs from the variant illustrated in FIG. 1 in that the CVD coating is also carried out at a plurality of positions. In the state of the device which is shown in FIG. 2, the coating station 35 is located in a first coating position, the coating station 36 is located in a second coating position and the coating station 37 is located in a third coating position. In each of these positions, the coating stations are connected to a means 25 for generating microwaves via hollow waveguides 23. The microwaves which are passed into the coating stations via the hollow waveguides 23 then generate a plasma in the regions in which the process gas is located, whereupon the reaction products formed in the plasma are deposited on those surfaces of the workpieces which are in contact with the plasma. As with the device shown in FIG. 1, this variant too can be designed to effect internal coating of workpieces which are in the form of hollow bodies, such as for example plastic bottles. It is also possible for different process gases to be supplied in the individual positions, with the result that different coatings are then applied at each of the individual positions. To allow gas exchange during the coating operation, the coating stations which are respectively located at the coating positions are connected to a further pump device 194 via feedlines 17.

The pallets can be supplied and removed in the same way as in the embodiment shown in FIG. 1. In the position of the device 1 which is shown in FIG. 2, the coating station 31 is in the feed position and the coating station 38 is in the unloading position.

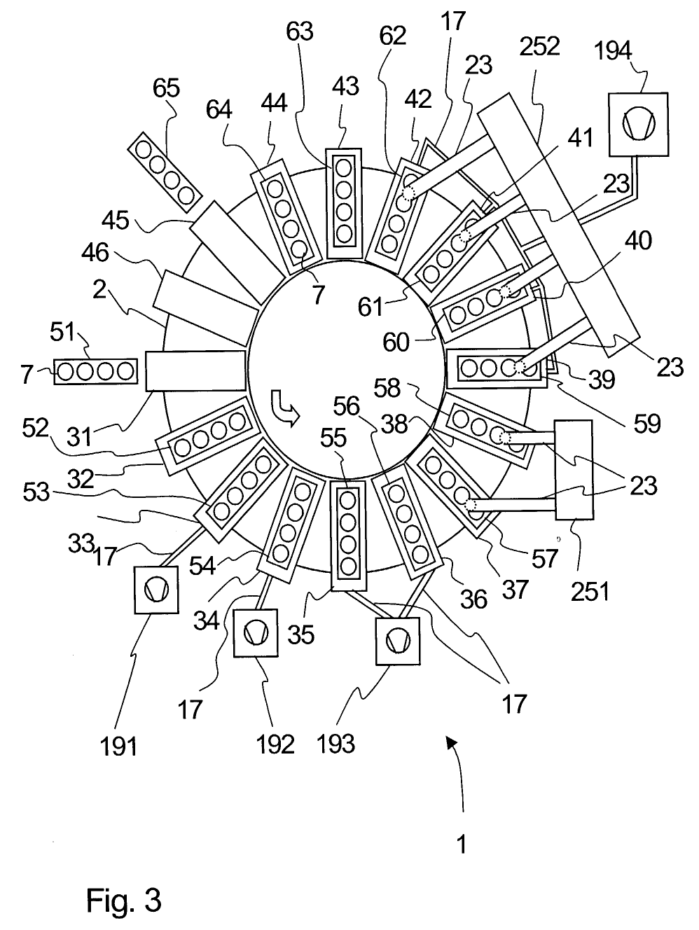

The following text refers to FIG. 3, which illustrates a further embodiment of the invention. This embodiment comprises 16 coating stations 31-45, which, in a similar manner to the embodiments which have been illustrated with reference to FIGS. 1 and 2, receive holders in the form of pallets 51-64. The pallets 51-64 have receivers 7 for in each case four workpieces. As in the embodiment shown in FIG. 2, the coating stations are evacuated by three vacuum pump stages 191, 192, 193. In this case, two evacuation positions, at which, in the position of the device 1 which is illustrated, the coating stations 35 and 36 are located, are assigned to the final pump stage 193. Therefore, the coating stations are connected to the last pump stage for in each case twice as long as they are connected to the other two pump stages. This is advantageous since the suction capacity of vacuum pumps drops as the pressure falls.

The coating is carried out in two stages, the first stage being assigned two coating positions and the second stage being assigned four coating positions. For this purpose, the coating stations are once again connected to hollow waveguides 23 which are connected to means for generating microwaves 251 and 252. During a change of coating position, the hollow waveguides can be connected up again or can be carried along in order to avoid interruption to the CVD coating.

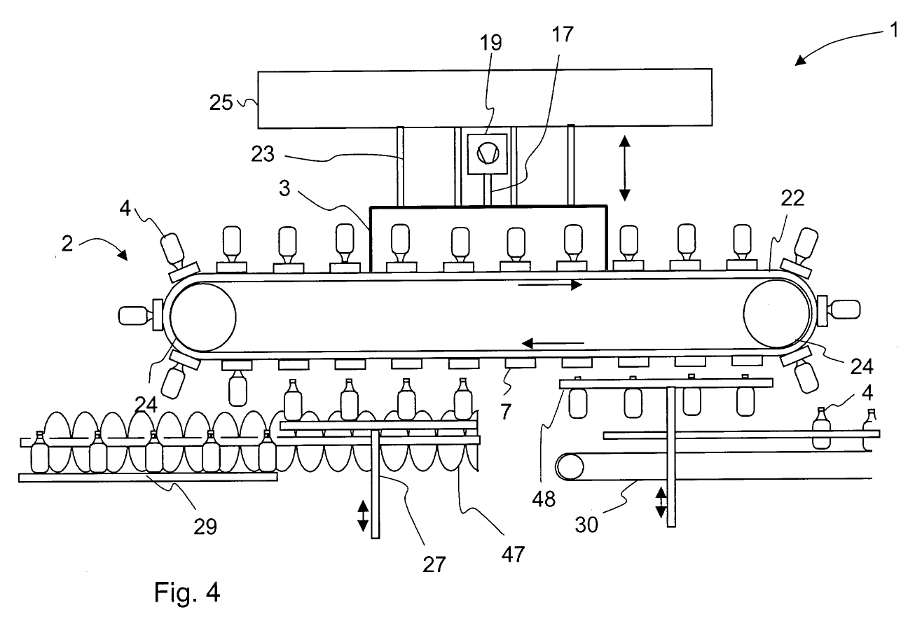

FIG. 4 shows a diagrammatic view of a device according to the invention designed as a rectilinear conveyor. The conveyor 2 of this embodiment comprises a conveyor chain 22 which is guided by rolls 23. The conveying direction of the conveyor chain 22 guided around the rolls 24 is indicated by arrows. Receiver 7 for receiving and securing bottles 4 are secured to the conveyor chain. The bottles 4 are inserted and removed on the opposite side from the conveyor chain 22. This creates a very compact structure for the device 1.

First of all, the bottles 4 are conveyed to the device 1 on a conveyor rail 29 with a conveyor screw 47, and they are then pushed into the receiving means 7 from below by means of a pusher 27. The pusher 27 is preferably designed in such a way that a plurality of bottles 4 can be simultaneously pushed into the receiver 7. The bottles 4 are put down on the pusher 27 at defined intervals, which correspond to the distances between the receiver 7 on the conveyor chain, by means of the conveyor worm 47. However, as an alternative to a pusher, it is also possible to use one or more robot gripper arms or a similar means. Moreover, the receiver 7 may also have clamps as means for securing the bottles.

The bottles that have been secured in the receiving means 7 are then conveyed to the opposite side by the conveyor chain 22. In a further step, a coating station 3 is lowered, so that the bottles are received in the coating station on the top side of the conveyor. Unlike in the embodiments described above, in this embodiment the coating station is not conveyed with the conveyor 2. In this case, the coating station 3 is preferably designed in such a way that the number of the bottles 4 which can be received therein corresponds to the number of bottles simultaneously pushed into the receiver 7 by the pusher 27 in order to make it possible to exploit the advantages of the simultaneous coating of a plurality of workpieces in a common coating station in accordance with the invention. The version of this embodiment which is illustrated in FIG. 4, with one coating station for in each case four bottles, is given merely by way of example.

Then, the interior of the coating station is pumped out by an evacuation means 19, which is only symbolically indicated and is connected to the coating station 3 via one or more vacuum lines 17.

Then, the process gas can be introduced into the interior of the bottles 4, where it can ignite a plasma by means of a means 25 for generating microwaves which is connected to the coating station 3 via hollow waveguides 23. Both the means 25 for generating microwaves and the evacuator 19 may, by way of example, be fixedly connected to the coating station 3 and raised and lowered together with this coating station 3. These means may also be connected to the coating station 3 via flexible or disconnectable connections, with the result that the means 25 and 19 can be arranged in a stationary position.

After the coating has taken place, the interior of the coating station is vented, the coating station 3 is raised again and the bottles are conveyed onward by the conveyor chain until they move back to the underside of the conveyor 2. From there, the bottles 4 can then be removed from the receiving means 7 by means of a removal means 48 and put down on a conveyor belt 30 in order to be conveyed onward. An arrangement of this type inter alia enables the bottles to be conveyed to the device 1 in an upright position and also conveyed onward in an upright position, with the result that the conveying technique used in filling plants can be utilized for conveying without major modifications being required.

List of Reference Symbols

1 CVD coating device

2 Conveyor

21 Inner region of the conveyor

22 Conveyor chain

23 Rolls

3, 31-46 Coating stations

51-65 Pallets

4 Bottle

7 Receivers for workpieces

9 Feed position

11 Pump position

13 Coating position

15 Unloading position

17 Vacuum line

19 Evacuator

191-194 Pump devices

23 Hollow waveguides

24 Roll

25, 251, 252 Devices that generate microwaves

27 Pusher

29 Conveyor rails

30 Conveyor belt

47 Conveyor worm

48 Remover

We claim:

1. A CVD coating device (1), comprising a conveyor (2), at least one coating station (3, 31-46) for coating workpieces, at least one evacuator (19) and a device that generates a plasma in at least one subregion of the coating station (3, 31-46), wherein at least two workpieces can be received in the at least one coating station (3, 31-46).

2. The device as claimed in claim 1, wherein the at least one coating station (31-46) is conveyed with the conveyor (2).

3. The device as claimed in claim 2, wherein the conveyor (2) successively conveys the coating station (31-46) from at least one feed position (9) to at least one evacuation position (11), at least one coating position (13) and at least one unloading position (15).

4. The device as claimed in claim 3, which includes at least four coating stations (31-34), which are arranged on the conveyor (2) in such a way that in each case one of the coating stations (31-34) is located in the at least one feed position (9), the at least one evacuation position (11) and the at least one discharge position (15) when one of the coating stations (31-34) is in the at least one coating position (13).

5. The device as claimed in claim 1, wherein the device that generates a plasma in at least one subregion of the coating station (31-46) comprises a device that generates a pulsed plasma.

6. The device as claimed in claim 1, wherein the workpieces are arranged on at least one holder (51-65) which can be received in the at least one coating station (3, 31-46).

7. The device as claimed in claim 1, wherein the workpieces are arranged on at least two levels in the coating station.

8. The device as claimed in claim 1, wherein the conveyor (2) slows the conveying speed, and in particular stops, during the coating.

9. The device as claimed in claim 1, wherein the conveyor (2) comprises a rotary device.

10. The device as claimed in claim 1, wherein the conveyor (2) comprises a rectilinear device.

11. The device as claimed in claim 1, wherein the device that generates a plasma in at least one subregion of the coating station (3, 31-46) comprises a device 25 that generates electromagnetic waves (25).

12. The device as claimed in claim 11, in which the device that generates electromagnetic waves comprises a device (25) that generates microwaves.

13. The device as claimed in claim 11, which includes a device (23) that connects the device that generates electromagnetic waves (25) to the at least one coating station (3, 31-46).

14. The device as claimed in claim 11, wherein the device that generates electromagnetic waves (25) is arranged in a stationary position.

15. The device as claimed in claim 1, wherein the evacuator (19) comprises at least two pump stages (191, 192, 193).

16. The device as claimed in claim 15, which comprises a device that sequentially connects the at least one coating station (3, 31-46) to the at least two pump stages (191, 192, 193).

17. The device as claimed in claim 1, which comprises a device that admits process gases.

18. The device as claimed claim 1, which comprises a device that secures the at least two workpieces.

19. The device as claimed in claim 18, in which the securing device comprises a receiver (7) for workpieces which are in the form of hollow bodies, in particular bottles (4).

20. The device as claimed in claim 19, wherein the evacuator (19) comprises a device that evacuates the cavity in the workpieces which are in the form of hollow bodies.

21. The device as claimed in claim 18, which comprises a device that admits process gas to the cavity in the workpieces which are in the form of hollow bodies.

22. A process for the CVD coating of workpieces using a CVD coating device, in particular using the CVD coating device, which comprises the steps of:
introducing at least two workpieces into a coating station (3, 31-46)
evacuating,
conveying the at least one coating station (31-46) with a conveyor (2),
generating a plasma in at least one subregion of the coating station (31-46),
venting, and
removing the workpieces.

23. The method as claimed in claim 22, which comprises the step of conveying the at least one coating station with the conveyor.

24. The process as claimed in claim 23, wherein the step of generating a plasma in at least one subregion of the coating station (31-46) comprises the step of generating a pulsed plasma.

25. The process as claimed in claim 23, wherein the step of generating a plasma in at least one subregion comprises the step of joint CVD coating of at least two workpieces.

26. The process as claimed in claim 22, in which the step of introducing at least two workpieces into the at least one coating station (31-46) comprises the step of introducing a holder (51-65) on which the workpieces are arranged.

27. The process as claimed in claim 22, in which the step of conveying the coating station (31-46) with a conveyor (2) comprises the steps of conveying from a feed position (9) to an evacuation position (11), a coating position (13) and an unloading position (15).

28. The process as claimed in claim 22, wherein the step of conveying the coating station (31-46) with a conveyor (2) comprises the step of slowing the conveying speed during the coating.

29. The process as claimed in claim 22, wherein the step of generating a plasma in at least one subregion of the coating station (31-46) comprises the step of generating electromagnetic waves.

30. The process as claimed in claim 22, which also comprises the step of connecting a device that generates electromagnetic waves (25) to the at least one coating station (31-46).

31. The process as claimed in claim 22, wherein the evacuation step comprises the step of sequential evacuation using at least two pump stages (191, 192, 193).

32. The process as claimed in claim 22, wherein the evacuation step comprises the step of evacuating the cavity of workpieces which are in the form of hollow bodies, in particular of bottles.

33. The process as claimed in claim 22, wherein the step of generating a plasma comprises the step of admitting a process gas.

34. The process as claimed in claim 33, in which the step of admitting a process gas comprises the step of admitting a process gas to the cavity in workpieces which are in the form of hollow bodies.

35. The process as claimed in claim 28, wherein the step of conveying the coating station with a conveyor 2 comprises the step of slowing the conveying speed during coating.

36. The process as claimed in claim 29, wherein the step of generating electromagnetic waves comprises the step of generating microwaves.

37. The device as claimed in claim 19, wherein the hollow bodies comprise bottles.
